(19) United States
(12) Patent Application Publication
(10) Pub. No.: US 2007/0023833 A1
(43) Pub. Date: Feb. 1, 2007

(54) Method for reading a memory cell having an electrically floating body transistor, and memory cell and array implementing same

(76) Inventors: Serguei Okhonin, Lausanne (CH); Mikhail Nagoga, Pully (CH)

Correspondence Address: Neil A. Steinberg, Suite 1150, 2665 Marine Way, Mountain View, CA, 94043, US

(21) Appl. No.: 11/453,594

(22) Filed: Jun. 15, 2006

Related U.S. Application Data
(60) Provisional application No. 60/703,142, filed on Jul. 28, 2005.

(51) Int. Cl. H01L 27/12

(52) U.S. Cl. 257/347; 257/296; 257/E27.084; 257/E29.117

(57) ABSTRACT

An integrated circuit device (for example, logic or discrete memory device) including a memory cell including an electrically floating body transistor, wherein the electrically floating body transistor includes a source region, a drain region, a body region disposed between the source region and the drain region, wherein the body region is electrically floating, and a gate disposed over the body region. The memory cell includes (i) a first data state which is representative of a first charge in the body region of the electrically floating body transistor, and (ii) a second data state which is representative of a second charge in the body region of the electrically floating body transistor. Circuitry, coupled to the electrically floating body transistor of the memory cell, (i) generates read control signals to perform a read operation of the memory cell and (ii) apply the read control signals to the electrically floating body transistor to sense the data state of the memory cell; wherein, in response to read control signals, the electrically floating body transistor replenishes charge in the body region of the electrically floating body transistor during the read operation. The electrically floating body transistor may be disposed on a bulk-type substrate or SOI-type substrate.

### RELATED APPLICATIONS

This application claims priority to U.S. Provisional Application Ser. No. 60/703,142, entitled “Method for Reading a Memory Cell Having an Electrically Floating Body Transistor, and Memory Cell, Array, and/or Device Implementing Same”, filed Jul. 28, 2005. The contents of this provisional application are incorporated by reference herein in its entirety.

### BACKGROUND

The inventions relate to a semiconductor memory cell, array, architecture and device, and techniques for controlling and/or operating such cell and device; and more particularly, in one aspect, to a semiconductor dynamic random access memory (“DRAM”) cell, array, architecture and/or device wherein the memory cell includes an electrically floating body in which an electrical charge is stored.

There is a continuing trend to employ and/or fabricate advanced integrated circuits using techniques, materials and devices that improve performance, reduce leakage current and enhance overall scaling. Semiconductor-on-Insulator (SOI) is a material in which such devices may be fabricated or disposed on or in (hereinafter collectively “on”). Such devices are known as SOI devices and include, for example, partially depleted (PD), fully depleted (FD) devices, multiple gate devices (for example, double or triple gate), and Fin-FET. SOI devices have demonstrated improved performance (for example, speed), reduced leakage current characteristics and considerable enhancement in scaling.

One type of dynamic random access memory cell is based on, among other things, a floating body effect of SOI transistors. (See, for example, U.S. Pat. 6,969,662). In this regard, the memory cell may consist of a PD or a FD SOI transistor (or transistor formed in bulk material/substrate) on having a channel, which is disposed adjacent to the body and separated therefrom by a gate dielectric. The body region of the transistor is electrically floating in view of the insulation or non-conductive region (for example, in bulk-type material/substrate) disposed beneath the body region. The state of memory cell is determined by the concentration of charge within the body region of the SOI transistor.

With reference to FIGS. 1A, 1B and 1C, in one embodiment, semiconductor DRAM array 10 includes a plurality of memory cells 12 each consisting of transistor 14 having gate 16, body region 18, which is electrically floating, source region 20 and drain region 22. The body region 18 is disposed between source region 20 and drain region 22. Moreover, body region 18 is disposed on or above region 24, which may be an insulation region (for example, in SOI material/substrate) or non-conductive region (for example, in bulk-type material/substrate). The insulation or non-conductive region 24 may be disposed on substrate 26.

Data is written into or read from a selected memory cell by applying suitable control signals to a selected word line(s) 28, a selected source line(s) 30 and/or a selected bit line(s) 32. In response, charge carriers are accumulated in or emitted and/or ejected from electrically floating body region 18 wherein the data states are defined by the amount of carriers within electrically floating body region 18. Notably, the entire contents of the Semiconductor Memory Device Patent Application, including, for example, the features, attributes, architectures, configurations, materials, techniques and advantages described and illustrated therein, are incorporated by reference herein.

As mentioned above, memory cell 12 of DRAM array 10 operates by accumulating in or emitting/ejecting majority carriers (electrons or holes) 34 from body region 18 of, for example, N-channel transistors. (See, FIGS. 2A and 2B). In this regard, accumulating majority carriers (in this example, “holes”) 34 in body region 18 of memory cells 12 via, for example, impact ionization near source region 20 and/or drain region 22, is representative of a logic high or “1” data state. (See, FIG. 2A). Emitting or ejecting majority carriers 30 from body region 18 via, for example, forward biasing the source/body junction and/or the drain/body junction, is representative of a logic low or “0” data state. (See, FIG. 2B).

Notably, for at least the purposes of this discussion, a logic high or State “1” corresponds to an increased concentration of majority carries in the body region relative to an unprogrammed device and/or a device that is programmed with a logic low or State “0”. In contrast, a logic low or State “0” corresponds to a reduced concentration of majority carries in the body region relative to an unprogrammed device and/or a device that is programmed with a logic high or State “1”.

Conventional reading is performed by applying a small drain bias and a gate bias above the transistor threshold voltage. The sensed drain current is determined by the charge stored in the floating body giving a possibility to distinguish between a plurality of data states (for example, data states “1” and “0”). A floating body memory device may have two or more different current states corresponding to two or more different logical states (for example, two different current states corresponding to the two different logical states: “1” and “0”).

The reading may be performed using positive voltages applied to word lines 24. As such, transistors 14 of memory cell 12 are periodically pulsed between (1) a positive gate bias, which (a) drives majority carriers (“holes” for N-channel transistors) away from the interface between gate insulator 32 and body region 18 of transistor 14 and (b) causes minority carriers (“electrons” for N-channel type transistors) to flow from source region 20 and drain region 22 into a channel formed below gate 16, and (2) a negative gate bias, which causes majority carriers to accumulate in or near the interface between gate 16 and body region 18 of transistor 14.

With reference to FIG. 3A, a positive voltage applied to gate 16 provides a positive gate bias which causes (1) a channel of minority carriers 34 to form beneath gate 16 and (2) accumulation of majority carriers 30 in body region 18 in an area “opposite” the interface of gate 16 and body region 18. Here, minority carriers (i.e., electrons in an N-channel transistor) may flow in the channel beneath the interface of gate oxide 32 and floating body region 18 wherein some of the minority carriers 34 are “trapped”, for example, by or in defects within the semiconductor (typically created or caused by the transition from one material type to another).

With reference to FIG. 3B, when a negative voltage is applied to gate 16, the gate bias is negative which substantially eliminates the channel of minority carriers 34 beneath gate 16 (and gate oxide 34). However, some of minority carriers may remain “trapped” in the interface defects (illustrated generally by electrons 36).

Some of the trapped electrons 36 recombine with majority carriers which are attracted to gate 16 (due to the negative gate bias), and, as such, the net charge of majority carriers 30 located in floating body region 18 may decrease over time (compare, for example, FIG. 3C relative to FIG. 3A). This phenomenon may be characterized as charge pumping. Thus, pulsing between positive and negative gate biases (during read and write operations) may reduce the net quantity of charge in memory cell 12, which, in turn, may gradually eliminate the data stored in memory cell 12.

With reference to FIG. 4, when the data state of memory cell 12 is read or sensed using convention techniques, the charge pumping phenomenon may present a gradually reducing read current for a particular data state (data state “1” in the context of N-channel transistors). As a result, when memory cell 12 is read multiple times without refresh, the read window becomes more limited for each successive read operation.

Notably, while the descriptions and figures above correspond to the case of a negative holding voltage, the same phenomenon may be observed when the holding voltage is zero or slightly positive.

### SUMMARY OF THE INVENTIONS

There are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

In one aspect, the present inventions are directed to an integrated circuit device (for example, logic or discrete memory device) including a memory cell including an electrically floating body transistor (for example, an N-channel type transistor or a P-channel type transistor). The electrically floating body transistor includes a source region, a drain region, a body region disposed between the source region and the drain region, wherein the body region is electrically floating, and a gate disposed over the body region. The memory cell includes (i) a first data state which is representative of a first charge in the body region of the electrically floating body transistor, and (ii) a second data state which is representative of a second charge in the body region of the electrically floating body transistor. The integrated circuit device further includes circuitry, coupled to the electrically floating body transistor of the memory cell, to (i) generate read control signals to perform a read operation of the memory cell and (ii) apply the read control signals to the electrically floating body transistor to sense the data state of the memory cell; wherein, in response to read control signals, the electrically floating body transistor replenishes charge in the body region of the electrically floating body transistor during the read operation.

Notably, in one embodiment, in response to read control signals, the electrically floating body transistor replenishes more charge in the body region of the electrically floating body transistor when the transistor is in a first data state than when the transistor is in a second data state.

The read control signals may include a signal applied to each of the gate and drain region to provide impact ionization in the body region of the electrically floating body transistor. In another embodiment, the circuitry applies the read control signals to the electrically floating body transistor to sense the data state of the memory cell, wherein the read control signals include a signal applied to each of the gate and drain region to provide impact ionization in the body region of the electrically floating body transistor. The circuitry may include sense amplifier circuitry to sense the data state of the memory cell. Moreover, the electrically floating body transistor may be disposed on bulk semiconductor substrate or SOI substrate.

In another aspect, the present inventions are directed to an integrated circuit device (for example, logic or discrete memory device) including a memory cell including an electrically floating body transistor (for example, an N-channel type transistor or a P-channel type transistor) wherein the electrically floating body transistor is disposed in or on (collectively “on”) a semiconductor region or layer which resides on or above an insulating region or layer of a substrate. The electrically floating body transistor includes a source region having impurities to provide a first conductivity type, a drain region having impurities to provide the first conductivity type, and a body region disposed between the source region, the drain region and the insulating region or layer of the substrate, wherein the body region is electrically floating and includes impurities to provide a second conductivity type wherein the second conductivity type is different from the first conductivity type. The electrically floating body transistor also includes a gate spaced apart from the body region.

The memory cell includes (i) a first data state which is representative of a first charge in the body region of the electrically floating body transistor, and (ii) a second data state which is representative of a second charge in the body region of the electrically floating body transistor.

Further, the integrated circuit device includes circuitry, coupled to the electrically floating body transistor of the memory cell, to (i) generate read control signals to perform a read operation of the memory cell and (ii) apply the read control signals to the electrically floating body transistor to sense the data state of the memory cell. In response to read control signals, the electrically floating body transistor replenishes charge in the body region of the electrically floating body transistor during the read operation. Notably, in one embodiment, in response to read control signals, the electrically floating body transistor replenishes more charge in the body region of the electrically floating body transistor when the transistor is in a first data state than when the transistor is in a second data state.

In one embodiment, the read control signals include a signal applied to each of the gate and drain region to provide impact ionization in the body region of the electrically floating body transistor. In another embodiment, the circuitry applies the read control signals to the electrically floating body transistor to sense the data state of the memory cell, wherein the read control signals include a signal applied to each of the gate and drain region to provide impact ionization in the body region of the electrically floating body transistor. Moreover, the substrate may be a bulk-type substrate or an SOI-type substrate.

Further, in one embodiment, the circuitry may include sense amplifier circuitry to sense the data state of the memory cell. Notably, the circuitry may also include word line drivers.

Again, there are many inventions, and aspects of the inventions, described and illustrated herein. This Summary of the Inventions is not exhaustive of the scope of the present inventions. Moreover, this Summary of the Inventions is not intended to be limiting of the inventions and should not be interpreted in that manner. While certain embodiments have been described and/or outlined in this Summary of the Inventions, it should be understood that the present inventions are not limited to such embodiments, description and/or outline, nor are the claims limited in such a manner. Indeed, many other embodiments, which may be different from and/or similar to, the embodiments presented in this Summary, will be apparent from the description, illustrations and claims, which follow. In addition, although various features, attributes and advantages have been described in this Summary of the Inventions and/or are apparent in light thereof, it should be understood that such features, attributes and advantages are not required whether in one, some or all of the embodiments of the present inventions and, indeed, need not be present in any of the embodiments of the present inventions.

### BRIEF DESCRIPTION OF THE DRAWINGS

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, materials and/or elements, other than those specifically shown, are contemplated and are within the scope of the present inventions.

Moreover, there are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

FIG. 1A is a schematic representation of a prior art DRAM array including a plurality of memory cells comprised of one electrically floating body transistor;

FIG. 1B is a three dimensional view of an exemplary prior art memory cell comprised of one electrically floating body transistor (PD-SOI NMOS);

FIG. 1C is a cross-sectional view of the prior art memory cell of FIG. 1B, cross-sectioned along line C-C′ (see, FIG. 1B);

FIGS. 2A and 2B are exemplary schematic illustrations of the charge relationship, for a given data state, of the floating body, source and drain regions of a prior art memory cell comprised of one electrically floating body transistor (PD-SOI NMOS);

FIGS. 3A-3C are exemplary schematic and general illustrations of the charge relationship and charge pumping phenomenon caused by pulsing between positive and negative gate biases (during read and write operations) of the electrically floating body transistor of FIG. 1B;

FIG. 4 illustrates the read current changes caused by conventional reading methods;

FIG. 5A is an exemplary illustration of the reading technique in conjunction with a memory cell 12 having N-channel type transistor 14, according to one aspect of the present inventions, wherein the loss of the majority carriers (i.e., holes) due to the charge pumping (50) is compensated (at least partially) by the impact ionization (51);

FIG. 5B is an exemplary illustration of the reading technique in conjunction with a memory cell 12 having P-channel type transistor 14, according to one aspect of the present inventions, wherein the loss of the majority carriers (i.e., electrons) due to the charge pumping (50) is compensated (at least partially) by the impact ionization (51); and

FIG. 6 illustrates read current changes when the data state of memory cell 12 is read or sensed using the techniques of the present inventions wherein changes in the read current caused by the proposed non-destructive reading technique are relatively small in comparison to the conventional reading technique (compare, for example, FIG. 4);

FIG. 7 is a schematic block diagram illustration of a memory cell array 10, including a plurality of memory cells 12 (which may include one or more transistors 14), in conjunction with certain peripheral circuitry; and

FIGS. 8A and 8B are schematic block diagram illustrations of exemplary integrated circuit devices in which the memory cell array 10 (and certain peripheral circuitry) may be implemented, according to certain aspects of the present inventions, wherein FIG. 8A is a logic device (having logic circuitry and resident memory) and FIG. 8B is a memory device (having primarily of a memory array).

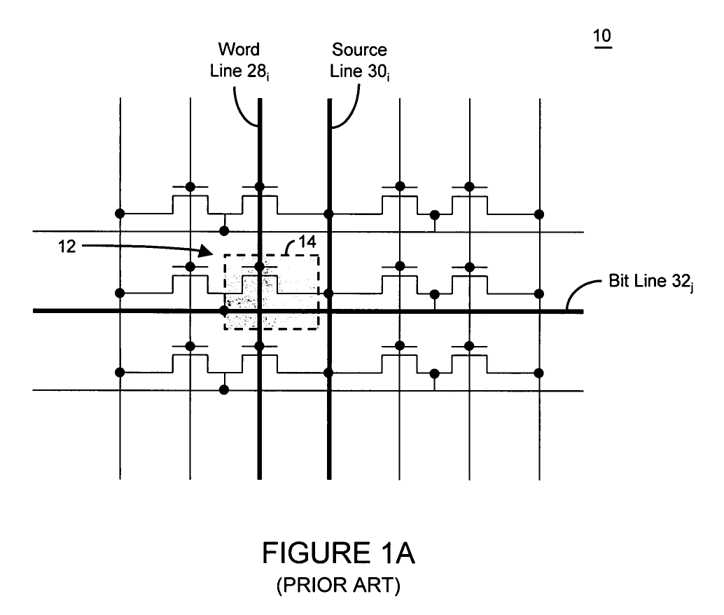

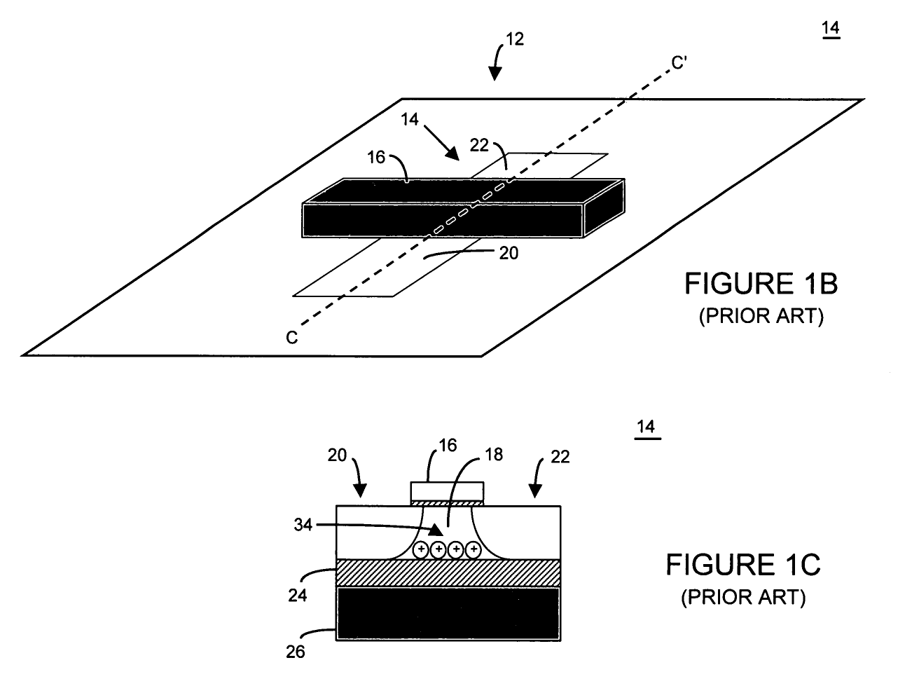

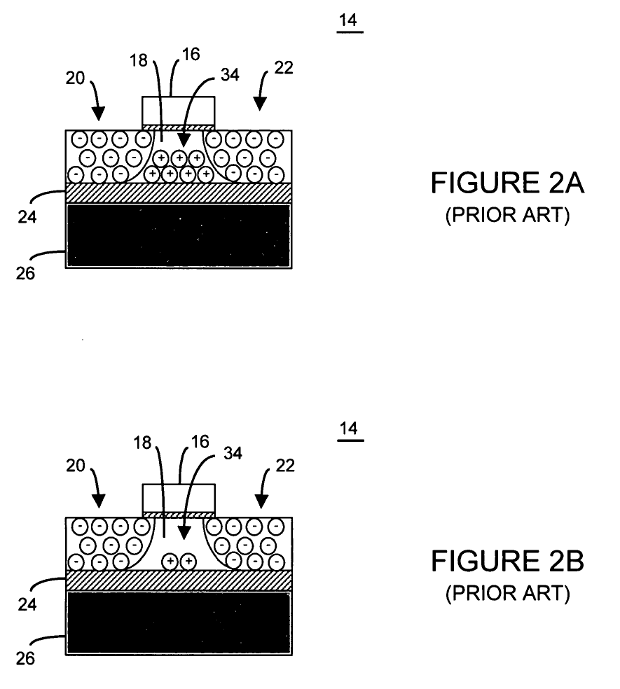

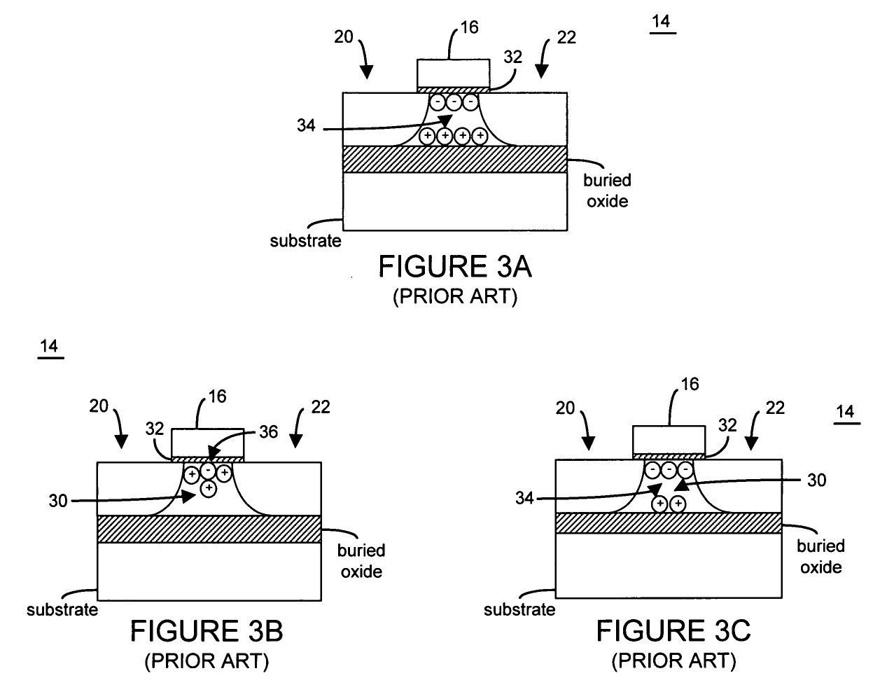

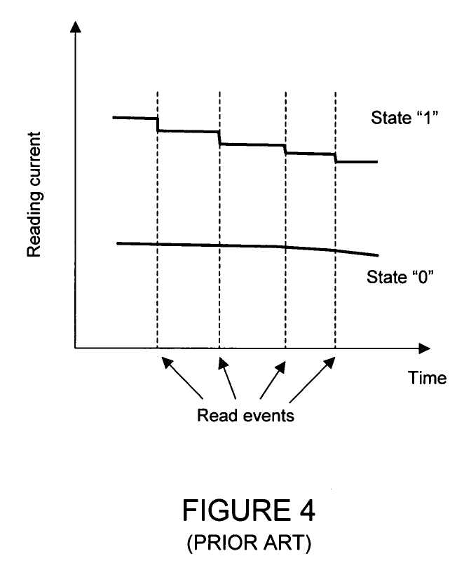

### DETAILED DESCRIPTION

At the outset, it should be noted that there are many inventions described herein as well as many aspects and embodiments of those inventions.

In one aspect, the present inventions are directed to techniques for reading, controlling and/or operating a semiconductor memory cell (and memory cell array having a plurality of such memory cells as well as an integrated circuit device including a memory cell array) having one or more electrically floating body transistors in which an electrical charge is stored in the body region of the electrically floating body transistor. The present inventions are also directed to semiconductor memory cell, array, and device that include circuitry to implement such reading, controlling and/or operating techniques. Notably, the memory cell and/or memory cell array may comprise a portion of an integrated circuit device, for example, a logic device (such as, a microcontroller or microprocessor) or a portion of a memory device (such as, a discrete memory).

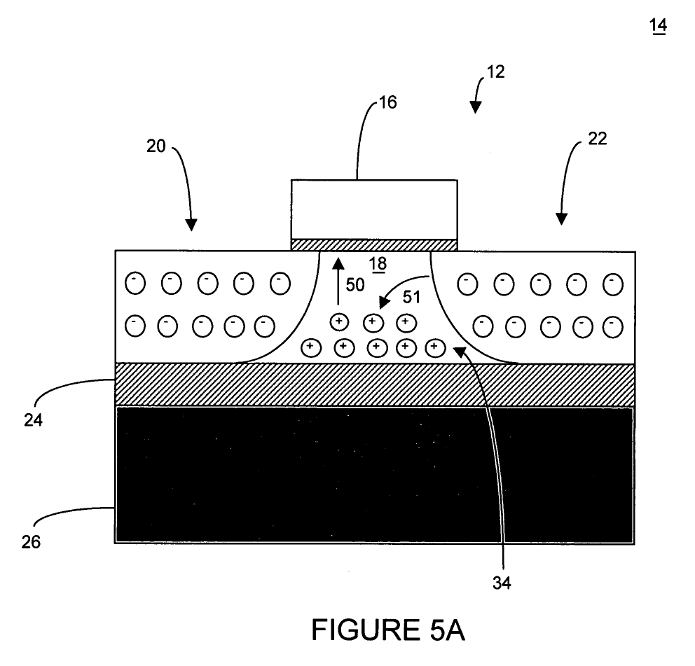

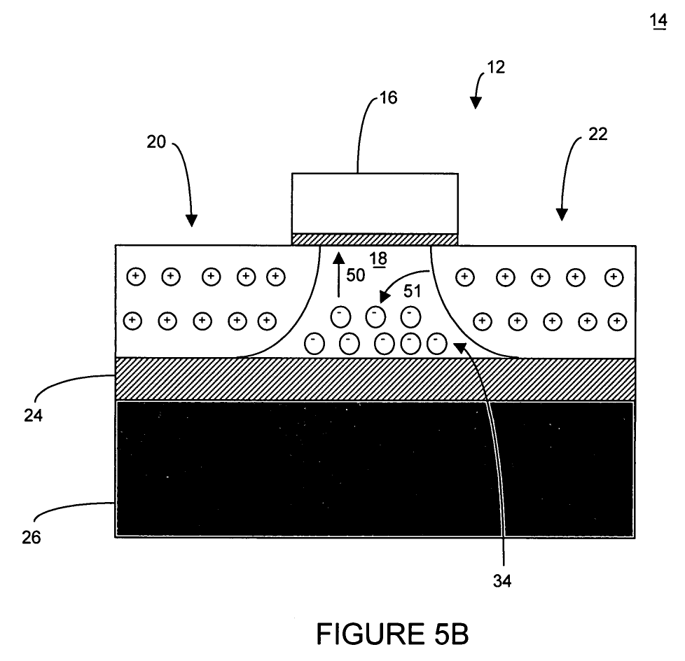

With reference to FIG. 5A, in one embodiment, the present inventions include memory cell 12 having electrically floating body transistor 14. In this exemplary embodiment, electrically floating body transistor 14 is an N-channel type device. As such, majority carriers 34 are “holes”.

During a read operation, in one embodiment, control signals (having predetermined voltages) are applied to gate 16 and source region 20 and drain region 22 of transistor 14 of memory cell 12 which, in combination, compensate (partially or fully) for the charge pumping effect/phenomenon during the read operation. The selected transistor 14 is read (via, for example, a current sense amplifier) by application of read control signals to electrically floating body transistor 14. In this regard, transistor 14 is read by applying a first voltage to source region 20 (for example, 0 volts), second voltage to gate 16 (a positive voltage which is about a threshold voltage (Vt) greater than the voltage applied to source region 20—for example, about 0.3 to 1.5 volts), and a third voltage to drain region 22 (a positive voltage which is higher than the voltage applied to gate 16 and source region 20, and large enough (relative to the gate and source voltages) to cause, induce or force impact ionization and/or the onset of impact ionization—for example, +1.6 volts or greater where the voltage applied to the gate is for example, about 0.3 to 1.5 volts). Under these circumstances, a high electric field area may develop or form in the vicinity of drain region 22, which may cause, force and/or induce impact ionization 51. The impact ionization 51 may compensate or replenish (partially or fully) the majority charge in body region 18 of transistor 14 that is “lost” to or affected by the charge pumping effect/phenomenon which the electrically floating body transistor 14 experiences during a read operation.

Notably, in response to read control signals, the electrically floating body transistor replenishes more charge in the body region of the electrically floating body transistor when the transistor is in a “1” data state than when the transistor is in a “0” data state.

While the description above is set forth in the context of the charge-pumping phenomenon induced majority carrier charge loss during a reading operation, the memory operation and control technique (for example, reading operation) described herein may be employed to address majority carrier charge loss generally (for example, loss due to recombination, junction and/or gate oxide leakages).

With reference to FIG. 5B, in another exemplary embodiment, the present inventions include an electrically floating body transistor 14 which is a P-channel type device. As such, majority carriers 34 are “electrons”. Briefly, in operation in this embodiment, during the read operation, read control signals may be applied to electrically floating body transistor 14. In this regard, a first voltage to source region 20 (for example, 0 volts) may be applied to source region 20, a negative voltage applied to gate 16 (for example, a voltage of about a threshold voltage greater than the voltage applied to source region 20, for example, about −0.3 to −1.5 volts). Further, a negative voltage may be applied to drain 22 (for example, −1.8 volts where the voltage applied to source region 20 is, for example, about −0.3 to −1.5 volts) to cause, induce or force impact ionization and/or the onset of impact ionization.

Similar to the embodiment of FIG. 5A, under these circumstances, a high electric field area may develop or form in the vicinity of drain region 22, which may cause, force and/or induce impact ionization 51. The impact ionization 51 may compensate or replenish (partially or fully) the majority charge in body region 18 of transistor 14 that is “lost” to or affected by the charge pumping effect/phenomenon which the electrically floating body transistor 14 experiences during a read operation. As noted above, in response to read control signals, the electrically floating body transistor replenishes more charge in the body region of the electrically floating body transistor when the transistor is in a “1” data state than when the transistor is in a “0” data state.

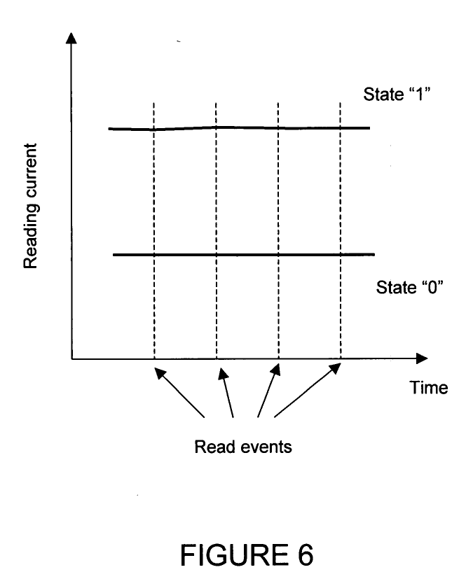

With reference to FIG. 6, when the data state of memory cell 12 is read or sensed using the techniques of the present inventions, the charge pumping effect/phenomenon, and a gradually reducing read current for a particular data state, may be contained, limited, minimized, compensated, or eliminated. As a result, when memory cell 12 is read multiple times without refresh, the read window is relatively stable for each successive read operation.

Thus, the reading technique described herein may reduce the degradation of the floating body charge caused by charge-pumping (charge-pumping disturb) thus allowing the quasi non-disturbing reading. As a result, when memory cell 12 is read multiple times without or before a refresh operation, the read window remains relatively stable for each successive read operation.

Notably, the amplitudes of the control voltages, set forth above, to implement the read operation are merely exemplary. The indicated voltage levels may be relative or absolute. Alternatively, the voltages indicated may be relative in that each voltage level, for example, may be increased or decreased by a given voltage amount (for example, each voltage may be increased or decreased by 0.25, 0.5, 1.0 and 2.0 volts) whether one or more of the voltages (for example, the source, drain or gate voltages) become or are positive and negative.

The present inventions may be implemented in any electrically floating body memory cell and memory cell array. For example, in certain aspects, the present inventions are directed to a memory array, having a plurality of memory cells each including an electrically floating body transistor, and/or technique of programming data into one or more memory cells of such a memory cell array. In this aspect of the inventions, the data states of adjacent memory cells and/or memory cells that share a word line may or may not be individually programmed.

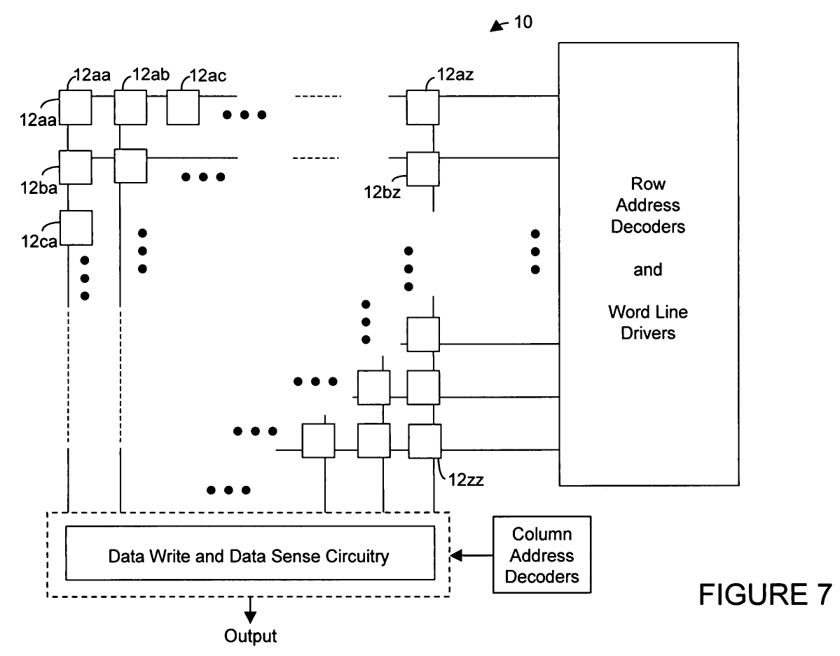

With reference to FIG. 7, memory array 10 may be comprised of a plurality of memory cells 12 of N-channel type, P-channel type and/or both types of electrically floating body transistors. The memory array 10 includes a plurality of rows and columns (for example, in a matrix form) of memory cells 12.

The circuitry which is peripheral to memory array 10 (for example, data sense circuitry (such as, for example, sense amplifiers or comparators), row and column address decoders, as well as word line drivers) may include P-channel type and/or N-channel type transistors. Where N-channel type transistors or P-channel type transistors are employed as memory cells 12 in memory array(s) 10, suitable write voltages are known to those skilled in the art. Accordingly, for sake of brevity, these discussions will not be repeated here.

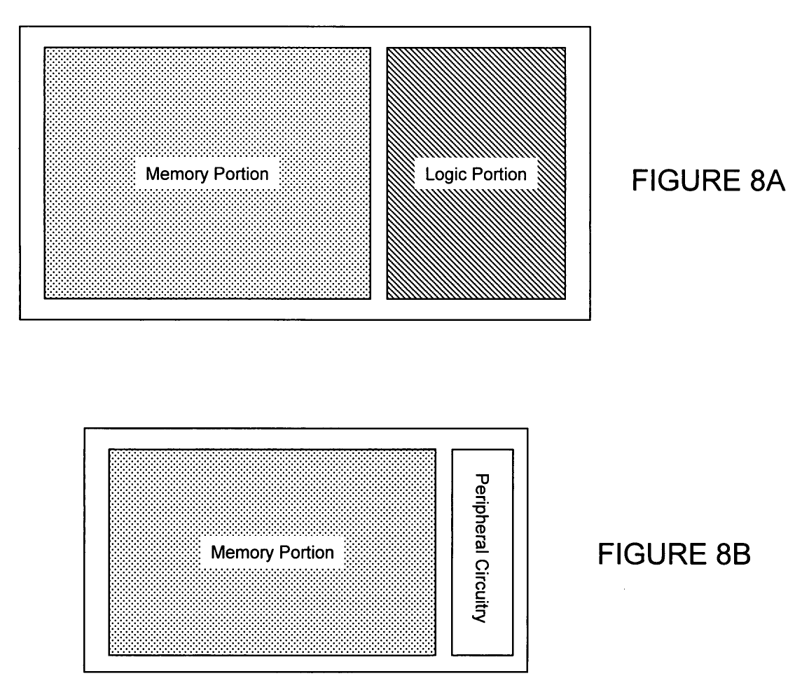

The memory cell 12 (having electrically floating body transistor 14) and memory cell array 10 of the present inventions may be implemented in an integrated circuit device having a memory portion and a logic portion (see, for example, FIG. 8A), or an integrated circuit device that is primarily a memory device (see, for example, FIG. 8B). Indeed, the present inventions may be implemented in any device having one or more memory cells 12 (having electrically floating body transistors) and/or memory cell arrays 10. For example, with reference to FIG. 7, an integrated circuit device may include array 10, having a plurality of memory cells 12 (having electrically floating body transistors), data write and sense circuitry, and memory cell selection and control circuitry (not illustrated). The data write and sense circuitry writes data into and senses the data state of one or more memory cells. The memory cell selection and control circuitry selects and/or enables one or more predetermined memory cells 12 to be read by data sense circuitry during a read operation.

For example, the electrically floating body transistor, which state is read using the techniques of the present inventions, may be employed in any electrically floating body memory cell, and/or memory cell array architecture, layout, structure and/or configuration employing such electrically floating body memory cells. In this regard, an electrically floating body transistor, which state is read by using the techniques of the present inventions, may be implemented in the memory cell, architecture, layout, structure and/or configuration described and illustrated in the following non-provisional U.S. patent applications:

(1) application Ser. No. 10/450,238, which was filed by Fazan et al. on Jun. 10, 2003 and entitled “Semiconductor Device” (now U.S. Pat. No. 6,969,662);

(2) application Ser. No. 10/487,157, which was filed by Fazan et al. on Feb. 18, 2004 and entitled “Semiconductor Device” (U.S. Patent Application Publication No. 2004/0238890);

(3) application Ser. No. 10/829,877, which was filed by Ferrant et al. on Apr. 22, 2004 and entitled “Semiconductor Memory Cell, Array, Architecture and Device, and Method of Operating Same” (U.S. Patent Application Publication No. 2005/0013163);

(4) application Ser. No. 10/840,009, which was filed by Ferrant et al. on May 6, 2004 and entitled “Semiconductor Memory Device and Method of Operating Same” (U.S. Patent Application Publication No. 2004/0228168); and

(5) application Ser. No. 10/941,692, which was filed by Fazan et al. on Sep. 15, 2004 and entitled “Low Power Programming Technique for a One Transistor SOI Memory Device & Asymmetrical Electrically Floating Body Memory Device, and Method of Manufacturing Same” (U.S. Patent Application Publication No. 2005/0063224).

The entire contents of these five (5) U.S. patent applications, including, for example, the inventions, features, attributes, architectures, configurations, materials, techniques and advantages described and illustrated therein, are hereby incorporated by reference herein. For the sake of brevity, those discussions will not be repeated; rather those discussions (text and illustrations), including the discussions relating to the memory cell, architecture, layout, structure, are incorporated by reference herein in its entirety.

Notably, the memory cells may be controlled (for example, programmed or read) using any of the control circuitry described and illustrated in the above-referenced five (5) U.S. patent applications. For the sake of brevity, those discussions will not be repeated; such control circuitry is incorporated herein by reference. Indeed, all memory cell selection and control circuitry for programming, reading, controlling and/or operating memory cells including electrically floating body transistors, whether now known or later developed, are intended to fall within the scope of the present inventions.

Moreover, the data write and data sense circuitry may include a sense amplifier (not illustrated in detail herein) to read the data stored in memory cells 12. The sense amplifier (for example, a cross-coupled sense amplifier as described and illustrated in the Non-Provisional U.S. patent application Ser. No. 11/299,590, filed by Waller and Carman, on Dec. 12, 2005 and entitled “Sense Amplifier Circuitry and Architecture to Write Data into and/or Read from Memory Cells”, the application being incorporated herein by reference in its entirety) may sense the data state stored in memory cell 12 using voltage or current sensing circuitry and/or techniques. In the context of a current sense amplifier, the current sense amplifier may compare the cell current to a reference current, for example, the current of a reference cell (not illustrated). From that comparison, it may be determined whether memory cell 12 contained a logic high (relatively more majority carriers 34 contained within body region 18) or logic low data state (relatively less majority carriers 34 contained within body region 18). Such circuitry and configurations thereof are well known in the art.

In addition, the present inventions may employ the reference generation techniques (used in conjunction with the data sense circuitry for the read operation) described and illustrated in U.S. Provisional Patent Application Ser. No. 60/718,417, which was filed by Bauser on Sep. 19, 2005, and entitled “Method and Circuitry to Generate a Reference Current for Reading a Memory Cell Having an Electrically Floating Body Transistor, and Device Implementing Same”. The entire contents of the U.S. Provisional Patent Application Ser. No. 60/718,417 are incorporated herein by reference. Further, the present inventions may also employ the read circuitry and techniques described and illustrated in U.S. patent application Ser. No. 10/840,902, which was filed by Portmann et al. on May 7, 2004, and entitled “Reference Current Generator, and Method of Programming, Adjusting and/or Operating Same” (now U.S. Pat. No. 6,912,150). The contents of U.S. Provisional Patent Application Ser. No. 60/718,417 and U.S. Pat. No. 6,912,150 are hereby incorporated by reference herein.

It should be further noted that while each memory cell 12 in the exemplary embodiments (described above) includes one transistor 14, memory cell 12 may include two transistors, as described and illustrated in application Ser. No. 10/829,877, which was filed by Ferrant et al. on Apr. 22, 2004 and entitled “Semiconductor Memory Cell, Array, Architecture and Device, and Method of Operating Same” (U.S. Patent Application Publication No. 2005/0013163). The contents of U.S. Patent Application Publication No. 2005/0013163 are hereby incorporated by reference herein The electrically floating memory cells, transistors and/or memory array(s) may be fabricated using well known techniques and/or materials. Indeed, any fabrication technique and/or material, whether now known or later developed, may be employed to fabricate the electrically floating memory cells, transistors and/or memory array(s). For example, the present inventions may employ silicon, germanium, silicon/germanium, gallium arsenide or any other semiconductor material (whether bulk-type or SOI) in which transistors may be formed. As such, the electrically floating memory cells may be disposed on or in (collectively “on”) SOI-type substrate or a bulk-type substrate.

Indeed, the electrically floating transistors, memory cells, and/or memory array(s) may employ the techniques described and illustrated in non-provisional patent application entitled “Integrated Circuit Device, and Method of Fabricating Same”, which was filed on Jul. 2, 2004, by Fazan, Ser. No. 10/884,481 (U.S. Patent Application Publication No. 2005/0017240), provisional patent application entitled “One Transistor Memory Cell having Mechanically Strained Electrically Floating Body Region, and Method of Operating Same”, which was filed on Oct. 19, 2005, Ser. No. 60/728,060, by Bassin, and/or provisional patent application entitled “Memory Cell, Array and Device, and Method of Operating Same”, which was filed on Oct. 19, 2005, Ser. No. 60/728,061, by Okhonin et al. (hereinafter collectively “Integrated Circuit Device Patent Applications”). The contents of the Integrated Circuit Device Patent Applications are hereby incorporated by reference herein.

Further, memory array 10 (including SOI memory transistors) may be integrated with SOI logic transistors, as described and illustrated in the Integrated Circuit Device Patent Applications. For example, in one embodiment, an integrated circuit device includes memory section (having, for example, PD or FD SOI memory transistors 14) and logic section (having, for example, high performance transistors, such as FinFET, multiple gate transistors, and/or non-high performance transistors (for example, single gate transistors that do not possess the performance characteristics of high performance transistors—not illustrated)).

Further, memory array(s) 10 may be comprised of N-channel, P-channel and/or both types of transistors, as well as partially depleted and/or fully depleted type transistors. For example, circuitry that is peripheral to the memory array (for example, sense amplifiers or comparators, row and column address decoders, as well as line drivers (not illustrated herein)) may include fully depleted type transistors (whether P-channel and/or N-channel type). Alternatively, such circuitry may include partially depleted type transistors (whether P-channel and/or N-channel type). There are many techniques to integrate both partially depleted and/or fully depleted type transistors on the same substrate (see, for example, application Ser. No. 10/487,157, which was filed by Fazan et al. on Feb. 18, 2004 and entitled “Semiconductor Device” (U.S. Patent Application Publication No. 2004/0238890)). All such techniques, whether now known or later developed, are intended to fall within the scope of the present inventions.

Notably, electrically floating body transistor 14 may be a symmetrical or non-symmetrical device. Where transistor 14 is symmetrical, the source and drain regions are essentially interchangeable. However, where transistor 14 is a non-symmetrical device, the source or drain regions of transistor 14 have different electrical, physical, doping concentration and/or doping profile characteristics. As such, the source or drain regions of a non-symmetrical device are typically not interchangeable. This notwithstanding, the drain region of the electrically floating N-channel transistor of the memory cell (whether the source and drain regions are interchangeable or not) is that region of the transistor that is connected to the bit line/sense amplifier.

As mentioned above, the memory arrays may be comprised of N-channel, P-channel and/or both types of transistors. Indeed, circuitry that is peripheral to the memory array (for example, sense amplifiers or comparators, row and column address decoders, as well as line drivers (not illustrated herein)) may include P-channel and/or N-channel type transistors. Where P-channel type transistors are employed as memory cells 12 in the memory array(s), suitable write and read voltages (for example, negative voltages) are well known to those skilled in the art in light of this disclosure. Accordingly, for sake of brevity, these discussions will not be repeated.

There are many inventions described and illustrated herein. While certain embodiments, features, attributes and advantages of the inventions have been described and illustrated, it should be understood that many others, as well as different and/or similar embodiments, features, attributes and advantages of the present inventions, are apparent from the description and illustrations. As such, the embodiments, features, attributes and advantages of the inventions described and illustrated herein are not exhaustive and it should be understood that such other, similar, as well as different, embodiments, features, attributes and advantages of the present inventions are within the scope of the present inventions.

For example, as mentioned above, the illustrated/exemplary voltage levels to implement the read and write operations are merely exemplary. The indicated voltage levels may be relative or absolute. Alternatively, the voltages indicated may be relative in that each voltage level, for example, may be increased or decreased by a given voltage amount (for example, each voltage may be increased or decreased by 0.1, 0.15, 0.25, 0.5, 1 volt) whether one or more of the voltages (for example, the source, drain or gate voltages) become or are positive and negative.

As mentioned above, each of the aspects of the present inventions, and/or embodiments thereof, may be employed alone or in combination with one or more of such aspects and/or embodiments. For the sake of brevity, those permutations and combinations will not be discussed separately herein. As such, the present inventions are neither limited to any single aspect (nor embodiment thereof, nor to any combinations and/or permutations of such aspects and/or embodiments.

Moreover, the above embodiments of the present inventions are merely exemplary embodiments. They are not intended to be exhaustive or to limit the inventions to the precise forms, techniques, materials and/or configurations disclosed. Many modifications and variations are possible in light of the above teaching. It is to be understood that other embodiments may be utilized and operational changes may be made without departing from the scope of the present inventions. As such, the foregoing description of the exemplary embodiments of the inventions has been presented for the purposes of illustration and description. Many modifications and variations are possible in light of the above teaching. It is intended that the scope of the inventions not be limited solely to the description above.

What is claimed is:

1. An integrated circuit device comprising:
a memory cell including an electrically floating body transistor, wherein the electrically floating body transistor includes:
a source region;
a drain region;
a body region disposed between the source region and the drain region, wherein the body region is electrically floating; and
a gate disposed over the body region; and
wherein the memory cell includes (i) a first data state which is representative of a first charge in the body region of the electrically floating body transistor, and (ii) a second data state which is representative of a second charge in the body region of the electrically floating body transistor; and
circuitry, coupled to the electrically floating body transistor of the memory cell, to (i) generate read control signals to perform a read operation of the memory cell and (ii) apply the read control signals to the electrically floating body transistor to sense the data state of the memory cell; and
wherein, in response to read control signals, the electrically floating body transistor replenishes charge in the body region of the electrically floating body transistor during the read operation.

2. The integrated circuit device of claim 1 wherein electrically floating body transistor is an N-channel type transistor.

3. The integrated circuit device of claim 1 wherein electrically floating body transistor is a P-channel type transistor.

4. The integrated circuit device of claim 1 wherein the read control signals include a signal applied to each of the gate and drain region to provide impact ionization in the body region of the electrically floating body transistor.

5. The integrated circuit device of claim 1 wherein the circuitry applies the read control signals to the electrically floating body transistor to sense the data state of the memory cell, wherein the read control signals include a signal applied to each of the gate and drain region to provide impact ionization in the body region of the electrically floating body transistor.

6. The integrated circuit device of claim 1 wherein electrically floating body transistor is disposed on bulk-type semiconductor substrate.

7. The integrated circuit device of claim 1 wherein electrically floating body transistor is disposed on SOI-type substrate.

8. The integrated circuit device of claim 1 wherein the circuitry includes sense amplifier circuitry and/or word line drivers.

9. The integrated circuit device of claim 1 wherein in response to the read control signals, the electrically floating body transistor replenishes more charge in the body region of the electrically floating body transistor when the transistor is in a first data state than when the transistor is in a second data state.

10. An integrated circuit device comprising:
a memory cell including an electrically floating body transistor, wherein the electrically floating body transistor disposed in or on a semiconductor region or layer which resides on or above an insulating region or layer of a substrate, the electrically floating body transistor includes:
a source region having impurities to provide a first conductivity type;
a drain region having impurities to provide the first conductivity type,
a body region disposed between the source region, the drain region and the insulating region or layer of the substrate, wherein the body region is electrically floating and includes impurities to provide a second conductivity type wherein the second conductivity type is different from the first conductivity type;
a gate spaced apart from the body region;
wherein the memory cell includes (i) a first data state which is representative of a first charge in the body region of the electrically floating body transistor, and (ii) a second data state which is representative of a second charge in the body region of the electrically floating body transistor;
circuitry, coupled to the electrically floating body transistor of the memory cell, to (i) generate read control signals to perform a read operation of the memory cell and (ii) apply the read control signals to the electrically floating body transistor to sense the data state of the memory cell; and
wherein, in response to read control signals, the electrically floating body transistor replenishes charge in the body region of the electrically floating body transistor during the read operation.

11. The integrated circuit device of claim 10 wherein electrically floating body transistor is an N-channel type transistor.

12. The integrated circuit device of claim 10 wherein electrically floating body transistor is a P-channel type transistor.

13. The integrated circuit device of claim 10 wherein the read control signals include a signal applied to each of the gate and drain region to provide impact ionization in the body region of the electrically floating body transistor.

14. The integrated circuit device of claim 10 wherein the circuitry applies the read control signals to the electrically floating body transistor to sense the data state of the memory cell, wherein the read control signals include a signal applied to each of the gate and drain region to provide impact ionization in the body region of the electrically floating body transistor.

15. The integrated circuit device of claim 10 wherein the substrate is a bulk-type semiconductor substrate.

16. The integrated circuit device of claim 10 wherein the substrate is an SOI-type substrate.

17. The integrated circuit device of claim 10 wherein the circuitry includes sense amplifier circuitry.

18. The integrated circuit device of claim 17 wherein the circuitry includes word line drivers.

19. The integrated circuit device of claim 10 wherein in response to the read control signals, the electrically floating body transistor replenishes more charge in the body region of the electrically floating body transistor when the transistor is in a first data state than when the transistor is in a second data state.
